(19) United States
(12) Patent Application Publication
(10) Pub. No.: US 2022/0361313 A1
(43) Pub. Date: Nov. 10, 2022

(54) LOW PRESSURE PLASMA SPRAYING

(71) Applicant: TOCALO CO., LTD., Kobe-shi, Hyogo (JP)

(72) Inventors: Nobuyoshi KUROKI, Akashi-shi, Hyogo (JP); Tatsuo SUIDZU, Akashi-shi, Hyogo (JP)

(21) Appl. No.: 17/764,915

(22) PCT Filed: Sep. 29, 2020
(86) PCT No.: PCT/JP2020/036940

§ 371 Date: Mar. 29, 2022

(30) Foreign Application Priority Data
Sep. 30, 2019 (JP) 2019-181015

(51) Int. Cl. H05H 1/34; C23C 4/134; C23C 4/137

(52) U.S. Cl. CPC H05H 1/34; C23C 4/134; C23C 4/137

(57) ABSTRACT

A low pressure plasma spraying method includes turning working gas into plasma by direct-current arc to generate a plasma jet while setting a plasma power source output to 2 to 10 kW in a pressure reducing vessel and feeding raw material powder having an average particle size of 1 to 10 μm into the plasma jet from feeding ports of a thermal spraying gun to form a thermal sprayed coating, which can suppress transformation of the raw material powder and form a dense coating.

### PRIORITY AND CROSS REFERENCE TO RELATED APPLICATIONS

This application is the U.S. National Stage Application under 35 U.S.C. § 371 of International Application No. PCT/JP2020/036940, filed Sep. 29, 2020, designating the U.S. and published as WO 2021/065920 A1 on Apr. 8, 2021, which claims the benefit of Japanese Application No. JP 2019-181015, filed Sep. 30, 2019. Any and all applications for which a foreign or a domestic priority is claimed is/are identified in the Application Data Sheet filed herewith and is/are hereby incorporated by reference in their entirety under 37 C.F.R. § 1.57.

### TECHNICAL FIELD

The present invention relates to low pressure plasma spraying in which plasma spraying is performed under reduced pressure.

### BACKGROUND ART

A thermal spraying method is a surface treatment technique in which powder materials or wire materials composed of metals, ceramics, or the like are fed into combustion flame or a plasma jet to soften or melt them and then, softened or melted materials are sprayed on a surface of a substrate at high speed to form a thermal sprayed coating on the surface. As such a thermal spraying method, plasma spraying, high velocity flame spraying, gas flame spraying, arc spraying, and the like are known. According to the purpose, by selecting a suitable thermal spraying method among these various methods, a coating with the required quality can be obtained.

Among the various thermal spraying methods, the plasma spraying is a thermal spraying method in which electric energy is used as a heat source and a coating is formed by using argon, hydrogen, or the like as a plasma generating source. Because a heat source temperature is high and a flame speed is high, it is possible to form a dense coating by using a material having high melting point. For example, it is suitable as a method for producing a ceramics thermal sprayed coating. As the plasma spraying, atmospheric plasma spraying performed in the atmosphere is the most common, and low pressure plasma spraying performed under reduced pressure is also adopted according to the purpose.

Patent Literature 1 describes plasma spraying in which raw material powder having a particle size of 10 μm or less is fed into an axial powder feeding type plasma spraying gun and plasma spraying is performed in a pressure reducing chamber. It is stated that a dense coating having a porosity of 1% or less can be formed with good adhesion by performing plasma spraying under reduced pressure, i.e., by: feeding the fine raw material powder into the axial powder feeding type plasma spraying gun; and allowing almost completely melted raw material powder to collide with a work at high speed.

### CITATION LIST

### Patent Literature

[Patent Literature 1] Japanese Laid-Open Patent Publication No. H10-226869

### SUMMARY OF INVENTION

In the low pressure plasma spraying, raw material powder having a particle size of about 10 to 45 μm is generally used as a thermal spraying material, and the raw material powder is fed into a plasma jet generated at an output of about 30 to 80 kW to be melted or semi-melted. However, when thermal spraying is performed with a plasma jet at such a high output, transformation of the raw material powder may occur during a coating is formed. The term “transformation” means change in a crystal structure and/or a chemical composition.

In particular, when fine powder having a particle size of 10 μm or less as described in Patent Literature 1 is used, the degree of transformation becomes remarkable because the powder is greatly affected by heat history. On the other hand, if the output is set low so as to prevent transformation of the raw material powder from occurring, the raw material powder cannot be sufficiently melted.

As described above, conventional low pressure plasma spraying has a problem that it is difficult to form a coating without causing transformation of the raw material powder.

In view of problems of the prior art, the present invention has an object of providing low pressure plasma spraying capable of forming a dense coating and simultaneously suppressing transformation of the raw material powder.

The low pressure plasma spraying of the present invention is low pressure plasma spraying including:

turning working gas into plasma to generate a plasma jet while setting a plasma power source output to 2 to 10 kW in a pressure reducing vessel; and
feeding raw material powder having an average particle size of 1 to 10 μm into the plasma jet to form a thermal sprayed coating.

According to the present invention, because the plasma power source output is set to a low output of 2 to 10 kW in the pressure reducing vessel, transformation of the raw material powder can be suppressed even when fine powder having an average particle size of 10 μm or less is used. That is, by plasma spraying a fine powder material at a low output, it is possible to obtain a thermal sprayed coating which maintains a crystal structure and a chemical composition of the raw material powder. Further, because the average particle size of the raw material powder is small, a dense thermal sprayed coating can be obtained.

It is preferable powder having a particle size of 10 μm or more occupies 10 to 40% by volume of a total volume of the raw material powder. It is difficult to stably feed fine powder having a particle size of less than 10 μm into a plasma spraying gun in the event a conveying distance by using a conveying hose is long or when the fine powder is conveyed for a long time because agglomeration is likely to occur when the fine powder is conveyed. If a material which is difficult to be conveyed is conveyed for a long time, feeding of the material may become unstable during thermal spraying and denseness of a coating may decrease. By mixing a certain amount or more of the powder having a particle size of 10 μm or more with the fine powder having a particle size of less than 10 μm, conveying property of the entire raw material powder can be improved. Because the plasma power source output is set to a low output, the powder having a particle size of 10 μm or more does not form a coating and only the fine powder having a particle size of less than 10 μm forms a coating As a result, the denseness of the formed thermal sprayed coating is ensured.

It is preferable to perform a pretreatment step of removing moisture in the raw material powder having an average particle size of 1 to 10 μm before feeding the raw material powder into the plasma jet. By performing the pretreatment step, the conveying property of the fine powder can be improved without adding a certain amount of the powder having a particle size of 10 μm or more to the fine powder having a particle size of less than 10 μm. As the pretreatment step of removing moisture, heat drying under vacuum is preferable. By performing the heat drying under vacuum, the conveying property of the fine powder can be more improved.

It is preferable a pressure within the pressure reducing vessel is adjusted to 1 to 4 kPa. By adjusting the pressure to this range, a plasma jet suitable for thermal spraying is generated and resistance of atmospheric gas during flight of the raw material powder is reduced. As a result, even when the fine powder material as the raw material powder is plasma sprayed at a low output as described above, enough flight speed can be given to the raw material powder.

It is preferable the plasma jet is generated by direct-current arc. There is also a method of generating plasma by utilizing high frequency. However, when a method of generating plasma by using direct-current arc is adopted, the plasma spraying gun can be miniaturized and handling by a robot becomes easy As a result, workability is improved.

According to the present invention, the raw material powder having an average particle size of 1 to 10 μm is fed into the plasma jet generated while setting the plasma power source output to 2 to 10 kW in the pressure reducing vessel. As a result, a dense thermal sprayed coating can be formed with suppressing transformation of the raw material powder.

### BRIEF DESCRIPTION OF THE DRAWINGS

FIG. 1 is a schematic view of a low pressure plasma spraying apparatus for carrying out low pressure plasma spraying according to one embodiment of the present invention.

FIGS. 2A and 2B show each schematic cross-sectional view of a nozzle of a thermal spraying gun in the present embodiment. FIG. 2A shows a structure of a mode for feeding a powder material in a direction opposite to a traveling direction of a plasma jet. FIG. 2B shows a structure of a mode for feeding a powder material in a direction along the traveling direction of the plasma jet.

FIG. 3 is a view showing an example of a particle size distribution of raw material powder which can be used in the present embodiment.

FIGS. 4A and 4B show each cross-sectional photograph of a thermal sprayed coating by SEM when the coating is formed from YOF thermal spraying material in Example 1.

FIG. 4A is a photograph observed at 5000 magnification. FIG. 4B is a photograph observed at 10000 magnification.

FIG. 5A shows a result of XRD measurement for YOF thermal spraying material as raw material powder. FIG. 5B shows a result of XRD measurement for the thermal sprayed coating formed in Example 1.

FIGS. 6A and 6B show each cross-sectional photograph of a thermal sprayed coating by SEM when the coating is formed from YOF thermal spraying material in Comparative Example 1. FIG. 6A is a photograph observed at 3000 magnification. FIG. 6B is a photograph observed at 10000 magnification.

FIG. 7A shows a result of XRD measurement for YOF thermal spraying material as raw material powder. FIG. 7B shows a result of XRD measurement for the thermal sprayed coating formed in Comparative Example 1.

FIGS. 8A and 8B show each cross-sectional photograph of a thermal sprayed coating by SEM when the coating is formed from α-Al₂O₃ thermal spraying material in Example 2. FIG. 8A is a photograph observed at 1000 magnification. FIG. 8B is a photograph observed at 5000 magnification.

FIG. 9A shows a result of XRD measurement for α-Al₂O₃ thermal spraying material as raw material powder. FIG. 9B shows a result of XRD measurement for the thermal sprayed coating formed in Example 2.

FIGS. 10A and 10B show each cross-sectional photograph of a thermal sprayed coating by SEM when the coating is formed from α-Al₂O₃ thermal spraying material in Comparative Example 2. FIG. 10A is a photograph observed at 1000 magnification. FIG. 10B is a photograph observed at 5000 magnification.

FIG. 11A shows a result of XRD measurement for α-Al₂O₃ thermal spraying material as raw material powder. FIG. 11B shows a result of XRD measurement for the thermal sprayed coating formed in Comparative Example 2.

### DETAILED DESCRIPTION

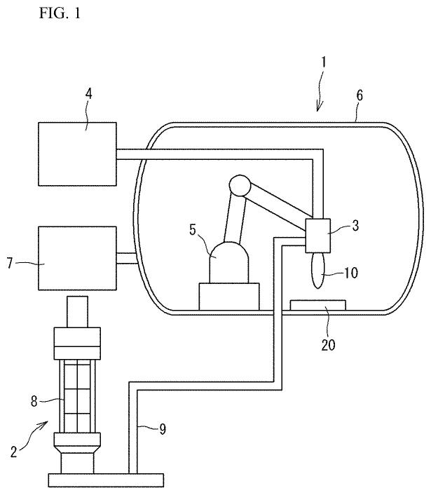

Embodiments of the present invention will be described. FIG. 1 is a schematic view of a low pressure plasma spraying apparatus 1 for carrying out low pressure plasma spraying according to one embodiment of the present invention. In the low pressure plasma spraying of the present embodiment, a pressure inside a vessel whose atmosphere can be controlled is reduced, and raw material powder as a thermal spraying material is fed into a plasma jet and allowed to collide with a surface to be subjected to coating formation at high speed to form a thermal sprayed coating.

Because the low pressure plasma spraying of the present embodiment is a coating formation process performed under an environment where an oxygen partial pressure is extremely low, even a metal-based thermal spraying material is scarcely oxidized and a coating which does not contain oxides can be formed, unlike atmospheric plasma spraying.

The low pressure plasma spraying apparatus 1 of the present embodiment is mainly provided with: a material feeding part 2 for feeding a thermal spraying material; a thermal spraying gun 3 for jetting a plasma jet 10; a plasma power source part 4 for supplying operating power to the thermal spraying gun 3; a six-axis robot 5 for moving the thermal spraying gun 3; a pressure reducing vessel 6 in which the thermal spraying gun 3 and the six-axis robot 5 are installed; and a vacuum pump 7 for reducing a pressure inside the pressure reducing vessel 6. A substrate 20 as the object of thermal spraying is placed in the pressure reducing vessel 6. A material of the substrate 20 is not limited. In the present embodiment, after the plasma jet 10 is generated, the pressure inside the pressure reducing vessel 6 is reduced.

The low pressure plasma spraying apparatus 1 of the present embodiment is additionally provided with: a voltage monitoring part for detecting a value of voltage to be applied; a power source control part for indicating a value of current to be supplied to the thermal spraying gun 3 to a power source part; and the like.

The material feeding part 2 is provided with: a hopper 8 for storing raw material powder; a conveying hose 9 for airflow-conveying the raw material powder carried out from the hopper 8 toward a feeding port of the thermal spraying gun 3 with carrier gas; and the like. As the hopper 8, a normal hopper for plasma spraying can be used. For example, a powder material is dropped from the hopper 8 onto a rotating disk located below the hopper 8, carrier gas is introduced into the material feeding part 2, and the powder material is fed into the conveying hose 9 by utilizing a pressure of the carrier gas.

The low pressure plasma spraying apparatus 1 may be provided with other members and/or devices as well as these constituent members.

The thermal spraying gun 3 is provided with: a gas supplying part for supplying primary gas and secondary gas which are working gases; and a feeding port for feeding the raw material powder into the plasma jet 10. The plasma jet 10 is generated by direct-current arc in the present embodiment. The thermal spraying gun 3 is provided with: a negative electrode; and a positive electrode, a current from a direct-current power source is supplied to the positive electrode and the negative electrode, and the direct-current arc is generated between the positive electrode and the negative electrode.

A plasma power source output for generating the plasma jet 10 is adjusted to 2 to 10 kw, which is lower than a conventional output. Because it becomes difficult to sufficiently heat and accelerate the raw material powder when the plasma power source output is less than 2 kW, the output is 2 kW or more. Because too much heat is applied to the raw material powder having a fine particle size and transformation of the raw material powder is likely to occur when the plasma power source output is more than 10 kw, the output is 10 kW or less. That is, in the present embodiment, the raw material powder having a fine particle size is formed into a coating without going through a melting process. As a result, there can be formed the coating which still maintains a crystal structure and a chemical composition of the raw material powder. The plasma power source output is an electric power consumed for generating the plasma jet.

When the direct-current arc is generated between the negative electrode and the positive electrode of the thermal spraying gun 3, the working gas introduced into the thermal spraying gun 3 is turned into plasma and jetted as the plasma jet 10. A thermal sprayed coating is formed by feeding the raw material powder into the plasma jet 10 and causing the powder to collide with the substrate 20.

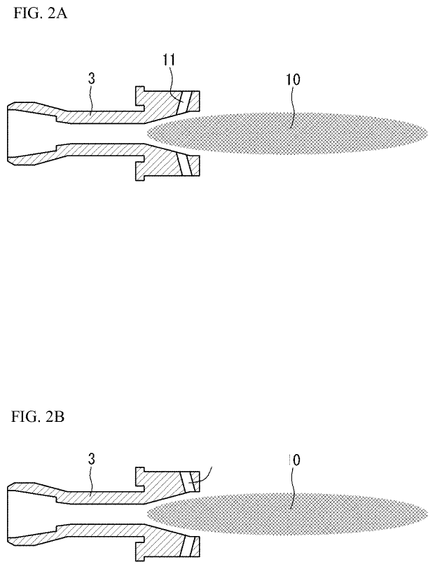

FIGS. 2A and 2B show each schematic cross-sectional view of a nozzle of the thermal spraying gun 3 in the present embodiment. FIG. 2A shows a structure of a mode for feeding a powder material in a direction opposite to a traveling direction of the plasma jet 10. FIG. 2B shows a structure of a mode for feeding a powder material in a direction along the traveling direction of the plasma jet 10. A plurality of feeding ports 11 for feeding the raw material powder into the plasma jet 10 are provided at a tip of the nozzle of the thermal spraying gun 3. From the feeding ports 11, the raw material powder is continuously fed from a direction oblique to the traveling direction (central axis) of the plasma jet 10. By feeding the raw material powder at the tip of the nozzle of the thermal spraying gun 3 in this way, it is possible to prevent the raw material powder from adhering to an inner wall of the thermal spraying gun 3.

A larger amount of a material can be fed into the center of the plasma jet 10 with the structure shown in FIG. 2A than the structure shown in FIG. 2B. That is, it is preferable to adopt the structure shown in FIG. 2A when it is desired to further heat and accelerate the raw material powder. On the other hand, because the raw material powder is formed into a coating without going through the melting process in the present embodiment, it is preferable to adopt the structure shown in FIG. 2B when it is rather desired to suppress heating. Furthermore, with the structure shown in FIG. 2B, there is an advantage that the raw material powder can be smoothly fed because the powder is fed in the direction along the traveling direction of the plasma jet 10.

In the structures shown in FIG. 2A and FIG. 2B, the raw material powder is fed from the direction oblique to the traveling direction of the plasma jet 10. However, the raw material powder may be fed from a direction perpendicular to the traveling direction of the plasma jet 10.

In the present embodiment, the thermal spraying material used as the raw material powder is not limited. Examples of the thermal spraying material include metals, ceramics, polymeric materials, and composites thereof. Examples of a composite composed of metals and ceramics includes cermet.

Examples of a metal material include a simple metal of an element selected from the group of Ni, Cr, Co, Cu, Al, Ta, Y, W, Nb, V, Ti, B, Si, Mo, Zr, Fe, Hf, La, and Yb, and alloys containing one or more of these elements.

Examples of a ceramics material include oxide ceramics, fluoride ceramics, carbide ceramics, nitride ceramics, boride ceramics, silicide ceramics, hydroxide ceramics, composite ceramics thereof, and mixtures thereof. Specific examples of the oxide ceramics include Al₂O₃, TiO₂, SiO₂, Cr₂O₃, ZrO₂, Y₂O₃, MgO, CaO, La₂O₃, Yb₂O₃, and composite oxides such as Al₂O₃—TiO₂ and Al₂O₃—SiO₂. Specific examples of the fluoride ceramics include YF₃, LiF, CaF₂, BaF₂, AlF₃, ZrF₄, and MgF₂. Specific examples of the carbide ceramics include TiC, WC, TaC, B₄C, SiC, HfC, ZrC, VC, and Cr₃C₂. Specific examples of the nitride ceramics include CrN, Cr₂N, TiN, TaN, AlN, BN, Si₃N₄, HfN, NbN, YN, ZrN, Mg₃N₂, and Ca₃N₂. Specific examples of the boride ceramics include TiB₂, ZrB₂, HfB₂, VB₂, TaB₂, NbB₂, W₂B₅, CrB₂, and LaB₆. Examples of the silicide ceramics include MoSi₂, WSi₂, HfSi₂, TiSi₂, NbSi₂, ZrSi₂, TaSi₂, and CrSi₂. Examples of the hydroxide ceramics include hydroxyapatite (Ca₅(PO₄)₃(OH)). Examples of composite ceramics composed of the carbide ceramics and the nitride ceramics include carbonitride ceramics such as Ti(C,N) and Zr(C,N). Examples of composite ceramics composed of the silicide ceramics and the oxide ceramics include silioxide ceramics such as Yb₂SiO₅, Yb₂Si₂O₇, and HfSiO₄. Examples of composite ceramics composed of the oxide ceramics and the fluoride ceramics include oxyfluoride ceramics such as YOF and LnOF (Ln is lanthanoid).

Examples of a cermet material include composites composed of: one or more ceramics selected from the group of WC, Cr₃C₂, TaC, NbC, VC, TiC, B₄C, SiC, CrB₂, WB, MoB, ZrB₂, TiB₂, FeB₂, AlN, CrN, Cr₂N, TaN, NbN, VN, TiN, and BN; and one or more metals selected from the group of Ni, Cr, Co, Cu, Al, Ta, Y, W, Nb, V, Ti, Mo, Zr, Fe, Hf, La, and Yb.

Examples of the polymeric material include nylon, polyethylene, tetrafluoroethylene-ethylene copolymer (ETFE), and the like.

Among the thermal spraying materials which can be applied in the present embodiment, examples of a material which is liable to be transformed under conditions of conventional plasma spraying (typically, the atmospheric plasma spraying or the low pressure plasma spraying in which an output is set to 20 kW or more) include: (i) a material which easily causes chemical change when a temperature is raised to become a different compound; (ii) a material which decomposes and vaporizes before melting when a temperature is raised; and (iii) a material which melts when a temperature is raised but causes change in a crystal structure after undergoing rapid solidification. Examples of the material (i) include YOF, LnOF, hydroxyapatite, and polymeric materials. Examples of the material (ii) include AlN, SiC, and Si₃N₄. Examples of the material (iii) include Al₂O₃ and TiO₂. For example, it is known that a thermal sprayed coating containing a large amount of γ-Al₂O₃ is formed from an α-Al₂O₃ thermal spraying material produced by a melt pulverization method by the rapid solidification after thermal spraying. In contrast, a thermal sprayed coating primarily containing α-Al₂O₃ can be formed from the α-Al₂O₃ thermal spraying material according to the low pressure plasma spraying of the present embodiment. Furthermore, it is known that a thermal sprayed coating containing a large amount of rutile-type TiO₂ is formed from an anatase-type TiO₂ thermal spraying material by the rapid solidification after thermal spraying. In contrast, a thermal sprayed coating primarily containing anatase-type TiO₂ can be formed from the anatase-type TiO₂ thermal spraying material according to the low pressure plasma spraying of the present embodiment. As described above, the low pressure plasma spraying of the present embodiment has a great feature in that it is possible to form a coating even from a material which is conventionally considered to be difficult to subject to thermal spraying.

In the present embodiment, powder having an average particle size of 1 to 10 μm is used as the raw material powder made of the thermal spraying material. In the present invention, the average particle size of the raw material powder is defined as a particle size (median diameter) at which a volume cumulative value is 50% when particle size distribution is measured by a laser diffraction-scattering method (Microtrac method). A particle size distribution measurement by the laser diffraction-scattering method (Microtrac method) can be performed by using, for example, MT3000II series commercially available from MicrotracBEL.

A pressure within the pressure reducing vessel in the present embodiment is preferably 20 kPa or less, and more preferably 1 to 4 kPa. Because diffusion of the plasma jet is suppressed and the raw material powder can be easily heated and accelerated, the pressure is more preferably 1 kPa or more. Because a flight speed is maintained by reducing resistance of atmospheric gas during flight of the raw material powder, so that coating formation property and the denseness of the coating are improved, the pressure is more preferably 4 kPa or less.

Examples of the working gas turned into the plasma, which can be used in the present embodiment, include argon, helium, nitrogen, hydrogen, and the like. Among these, an inert gas such as argon or helium is preferable from the viewpoint of suppressing transformation of the raw material powder. When hydrogen is used, a reduction reaction may be promoted and/or a substrate made of metal may embrittle by hydrogen. When nitrogen is used, a nitriding reaction may be caused.

Regarding a thermal spraying distance from the tip of the nozzle of the thermal spraying gun 3 to the substrate 20, normal low pressure plasma spraying requires a thermal spraying distance of about 200 to 500 mm. However, a thermal spraying distance is preferably about 30 to 90 mm, which is significantly shorter than normal, in the low pressure plasma spraying of the present embodiment. The reason for this preferable range of the thermal spraying distance is that a length (band) of the plasma jet 10 is shortened because the plasma power source output for generating the plasma jet 10 is a low output of 2 to 10 kW. By setting the thermal spraying distance to 30 to 90 mm, it is possible to make it easier for the raw material powder to reach the substrate 20.

In the present embodiment, the raw material powder is dry-conveyed with the carrier gas toward the feeding ports of the thermal spraying gun 3. When the particle size of the raw material powder is less than 10 μm, agglomeration of the raw material powder is likely to occur. As a result, the raw material powder may adhere to and accumulate on an inner wall of the conveying hose 9 in the event the conveying distance is long or when the raw material powder is conveyed for a long time. When an amount of the raw material powder adhering to the inner wall of the conveying hose 9 increases, a grain size and an amount of the powder fed into the plasma jet change. As a result, it becomes difficult to keep conditions for forming the coating uniform. If the conditions change during coating formation, it becomes difficult to form a thermal sprayed coating having uniform thickness and denseness.

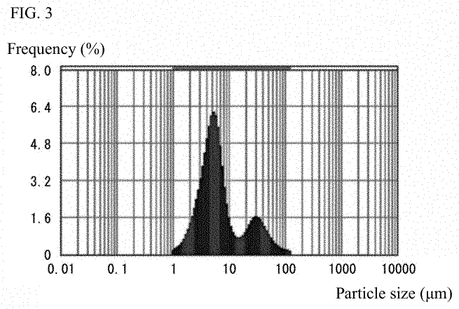

On the other hand, the present embodiment improves the above-mentioned problem by adopting the raw material powder in which powder having a particle size of 10 μm or more occupies a certain amount or more of the total volume of the raw material powder, in addition to having the average particle size of 1 to 10 μm. FIG. 3 is a view showing an example of a particle size distribution of the raw material powder which can be used in the present embodiment. As shown in FIG. 3, although the powder has an average particle size of 5.6 μm, the powder contains a certain amount of powder having a particle size of 10 μm or more. By mixing a certain amount or more of the powder having a particle size of 10 μm or more, it is possible to facilitate conveying of the fine powder having a particle size of less than 10 μm simultaneously. Specifically, the powder having a particle size of 10 μm or more occupies preferably 10% by volume or more, and more preferably 20% by volume or more of the total volume of the raw material powder. The powder having a particle size of 10 μm or more may occupy 40% by volume or more of the total volume of the raw material powder, and conveying property is very high. However, because a proportion of powder which does not form a coating increases, coating formation efficiency is not so high. Therefore, the powder having a particle size of 10 μm or more occupies preferably 40% by volume or less, and more preferably 30% by volume or less of the total volume of the raw material powder. The raw material powder in this case has preferably an average particle size of 1 to 8 μm, and more preferably an average particle size of 3 to 7 μm. The smaller the average particle size of the raw material powder is, the easier it is to obtain a dense coating. On the other hand, when the average particle size is less than 1 μm, it is difficult to convey the powder even if a certain amount or more of the powder having a particle size of 10 μm or more is mixed, and the coating formation efficiency is low even if the powder can be conveyed. Alternatively, as another embodiment, a pretreatment step of removing moisture in the raw material powder may be performed before conveying the powder. By performing the pretreatment step, the conveying property can be improved without adding a certain amount of the powder having a particle size of 10 μm or more to the fine powder having a particle size of less than 10 μm. Examples of the pretreatment step of removing moisture include vacuum drying at ordinary temperature, heat drying in the atmosphere or under vacuum, and the like. The raw material powder in this case has preferably an average particle size of 1 to 8 μm, and more preferably an average particle size of 1 to 6 μm.

In a case of low pressure plasma spraying in which the plasma power source output is adjusted to a low output of 2 to 10 kw, a coating is not formed from the raw material powder having a particle size of 10 μm or more. It is considered the coating is not formed because the plasma jet generated at the low output cannot sufficiently heat and accelerate the raw material powder having a particle size of more than 10 μm, so that: the raw material powder does not reach the substrate; or particles of the raw material powder do not flatten when they collide with the substrate. As a result, a coating is formed from only the raw material powder having a particle size of less than 10 μm and the coating is dense.

(Powder Conveying Test 1)

There was carried out a test for investigating a relationship between: the amount of the powder having a particle size of 10 μm or more relative to the total volume of the raw material powder; and the conveying property of powder. The results are shown below. “Powder a” having an average particle size of 4.5 μm was prepared as the fine powder having a particle size of less than 10 μm. “Powder b” having an average particle size of 33.5 μm was prepared as the powder having a particle size of 10 μm or more. Details are shown in Table 1.

TABLE 1

| | | Powder a | Powder b |
|---|---|---|---|
| Particle size | D10 | 2.1 μm | 25.3 μm |
| | D50 | 4.5 μm | 33.5 μm |
| | D90 | 7.9 μm | 46.7 μm |

Subsequently, there were prepared: three kinds of mixed powder including “Mixed powder A”, “Mixed powder B”, and “Mixed powder C”, each having the mixing ratio of “Powder a” and “Powder b” shown in Table 2; and “Powder D” composed of “Powder a”. Each powder was continuously fed for 5 minutes into a plasma jet by using the thermal spraying gun with the nozzle having the structure of a mode for feeding a powder material shown in FIG. 2B. Then, pulsation during conveying of the powder was investigated by observing the plasma jet. The pulsation refers to a phenomenon in which agglomeration of fine powder occurs in a conveying path to increase a pressure inside the path, so that agglomerated powder blows out at once.

TABLE 2

| | Mixed powder A | | Mixed powder B | | Mixed powder C | | Powder D | |
|---|---|---|---|---|---|---|---|---|
| | Powder a | Powder b | Powder a | Powder b | Powder a | Powder b | Powder a | Powder b |
| Mixing ratio (mass ratio) | 70 | 30 | 80 | 20 | 90 | 10 | 100 | 0 |
| Mixing ratio (volume ratio) | 66 | 34 | 79 | 21 | 89 | 11 | 100 | 0 |

| | | | | | |
|---|---|---|---|---|---|
| Particle size | D10 | 3.2 μm | 2.6 μm | 2.7 μm | 2.1 μm |
| | D50 | 12.1 μm | 5.6 μm | 6.6 μm | 4.5 μm |
| | D90 | 41.5 μm | 32.9 μm | 26.4 μm | 7.9 μm |

The results are shown below.

Mixed powder A:

No pulsation occurred and stable feeding without interruption was achieved.

Mixed powder B:

No pulsation occurred and stable feeding without interruption was achieved.

Mixed powder C:

Pulsation occurred three times per 5 minutes. However, stable feeding with almost no problem was achieved.

### Powder D:

Pulsation occurred eight times per 5 minutes. Although there was no problem in coating formation, feeding was unstable.

(Powder Conveying Test 2)

There was carried out a test for investigating a relationship between: whether or not the pretreatment step of removing moisture in the raw material powder was carried out; and the conveying property of powder. The results are shown below. As test powder, “Powder D” shown in Table 2 was prepared.

By using “Powder D”, the test powder was prepared under each of the following eight conditions.

(a) Vacuum dried at 100° C. for 2 hours
(b) Vacuum dried at 100° C. for 4 hours
(c) Vacuum dried at 100° C. for 6 hours
(d) Vacuum dried at 100° C. for 8 hours
(e) Vacuum dried at 200° C. for 2 hours
(f) Vacuum dried at 200° C. for 4 hours
(g) Vacuum dried at 200° C. for 6 hours
(h) Vacuum dried at 200° C. for 8 hours
The amount of each powder was 700 g. There was used ADP300 commercially available from Yamato Scientific Co., Ltd. as a vacuum drying apparatus, and the degree of vacuum was adjusted to 0.1 MPa or less. Subsequently, the powder prepared under each of the above eight conditions was continuously fed for 5 minutes into a plasma jet by using the thermal spraying gun with the nozzle having the structure of a mode for feeding a powder material shown in FIG. 2B. Then, pulsation during conveying of the powder was investigated by observing the plasma jet.

The results are shown below.

### Condition (a):

Pulsation occurred four times per 5 minutes. However, stable feeding with almost no problem was achieved.

### Condition (b):

Pulsation occurred two times per 5 minutes. However, stable feeding with almost no problem was achieved.

### Condition (c):

Pulsation occurred once per 5 minutes. However, stable feeding with almost no problem was achieved.

### Condition (d):

No pulsation occurred and stable feeding without interruption was achieved.

### Condition (e):

Pulsation occurred once per 5 minutes. However, stable feeding with almost no problem was achieved.

### Condition (f):

No pulsation occurred and stable feeding without interruption was achieved.

### Condition (g):

No pulsation occurred and stable feeding without interruption was achieved.

### Condition (h):

No pulsation occurred and stable feeding without interruption was achieved.

As described above, the longer the vacuum drying time of the raw material powder was, the more improved the conveying property tended to be. Furthermore, in the case of vacuum drying, it was found that each of the following conditions is particularly preferable. That is, the conditions include: the drying temperature is 100° C. or higher and the drying time is 8 hours or longer; and the drying temperature is 200° C. or higher and the drying time is 4 hours or longer. On the other hand, the higher the drying temperature is, the more shortened the drying time can be. However, if the drying temperature is too high, workability may be reduced and transformation may occur depending on the material. Therefore, the drying temperature is preferably 400° C. or lower, more preferably 300° C. or lower. Effect of improving the conveying property of the powder can be exhibited by performing heat drying in the atmosphere or vacuum drying at ordinary temperature as well as heat drying under vacuum. However, powder subjected to the heat drying under vacuum shows the most excellent conveying property. Therefore, the heat drying under vacuum is most preferable as the pretreatment step of removing moisture in the raw material powder.

In the present embodiment, the thermal sprayed coating can be formed with a thickness of, for example, 1 μm or more and less than 100 μm. The thickness of the thermal sprayed coating may be 5 μm or more, and may be 50 μm or less or 40 μm or less. When the thickness is too large, there is a concern the thermal sprayed coating will peel off. When the thickness is too small, there is a concern the thermal sprayed coating will be insufficient as a coating. A porosity of the thermal sprayed coating can be, for example, 10% or less, and also can be 2% or less depending on conditions. The porosity can be calculated, for example, by the following method. That is, as pores there are regarded black portions in a coating of a cross-sectional photograph by a scanning electron microscope (SEM-BEI image), the black portions are binarized, a total area of the pores is calculated, and the total area of the pores is divided by a total area of the coating within the observed range.

### EXAMPLES

Coatings were formed by: the low pressure plasma spraying in which the output was set to a low output as in the above embodiment; and a conventional low pressure plasma spraying in which the output was set to a high output. The cross section of each coating was photographed and each coating was subjected to XRD measurement. Test conditions are as shown below.

### Example 1

An aluminum flat plate having a length of 50 mm, a width of 50 mm, and a thickness of 5 mm was prepared as a substrate. The low pressure plasma spraying was performed under the following conditions by using the aluminum flat plate and YOF sintered-pulverized powder having an average particle size of 4.5 μm (grain size range: 2 to 9 μm) as a thermal spraying material. As the nozzle of the thermal spraying gun, one having the structure shown in FIG. 2B was used.

### <Thermal Spraying Conditions>

Atmosphere inside vessel: Ar
Pressure inside vessel: 2 kPa
Direct-current power source output: 4.8 kW (150 A)
Plasma generating gas: Ar
Thermal spraying distance: 50 mm

### Comparative Example 1

A flat plate of SS400 steel, having a length of 50 mm, a width of 50 mm, and a thickness of 5 mm, was prepared as a substrate. The low pressure plasma spraying was performed under the following conditions by using the flat plate of SS400 steel and YOF sintered-pulverized powder having an average particle size of 4.5 μm (grain size range: 2 to 9 μm) as a thermal spraying material. As the nozzle of the thermal spraying gun, one having the structure shown in FIG. 2B was used.

### <Thermal Spraying Conditions>

Atmosphere inside vessel: Ar
Pressure inside vessel: 18 kPa
Direct-current power source output: 42 kW (700 A)
Plasma generating gas: Ar, H₂
Thermal spraying distance: 275 mm

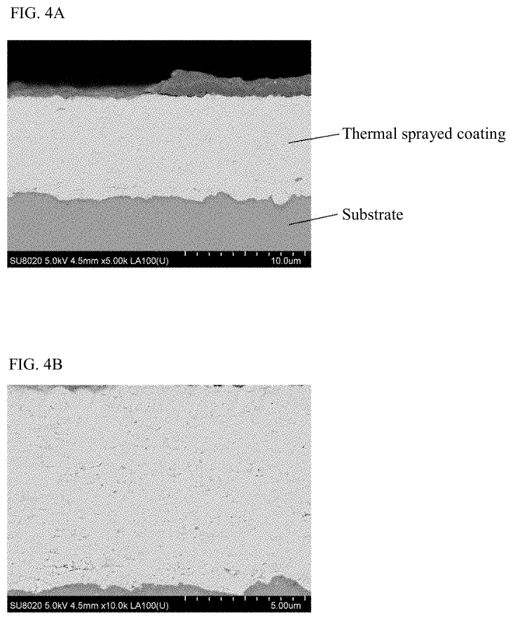

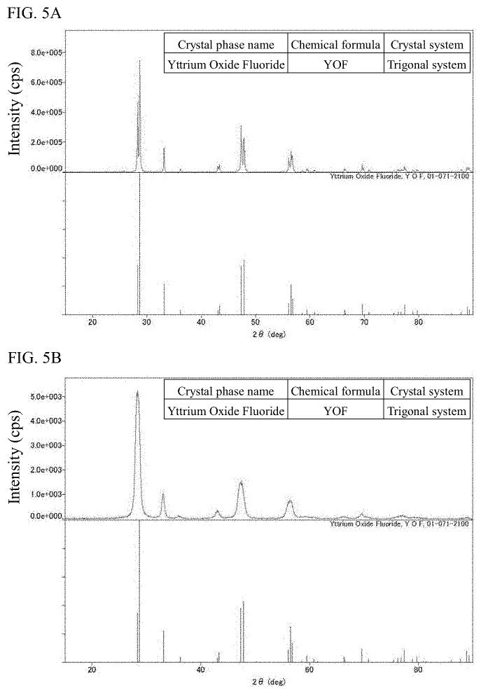

FIGS. 4A and 4B show each cross-sectional photograph of a thermal sprayed coating by a scanning electron microscope (SEM) when the coating is formed from the YOF thermal spraying material in Example 1. FIG. 4A is a photograph of the thermal sprayed coating, which is observed at 5000 magnification. FIG. 4B is a photograph of the thermal sprayed coating, which is observed at 10000 magnification. The thickness of the thermal sprayed coating formed in Example 1 was about 10 μm. FIG. 5A shows the result of XRD measurement for the YOF thermal spraying material as the raw material powder. FIG. 5B shows the result of XRD measurement for the thermal sprayed coating formed in Example 1.

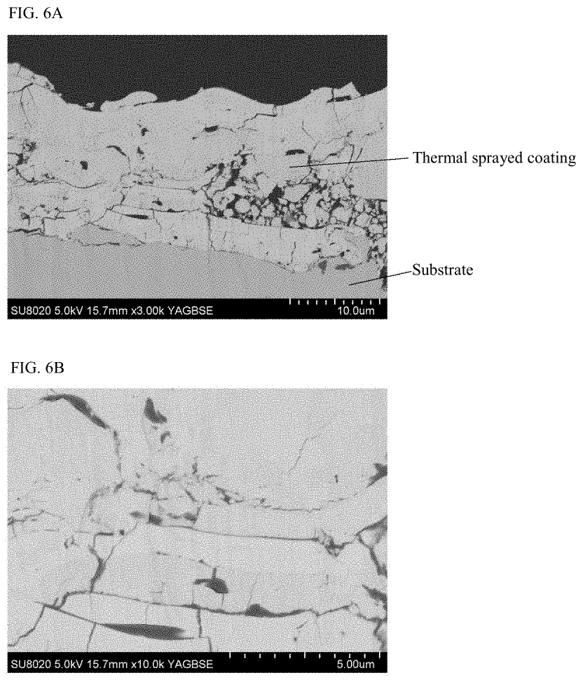

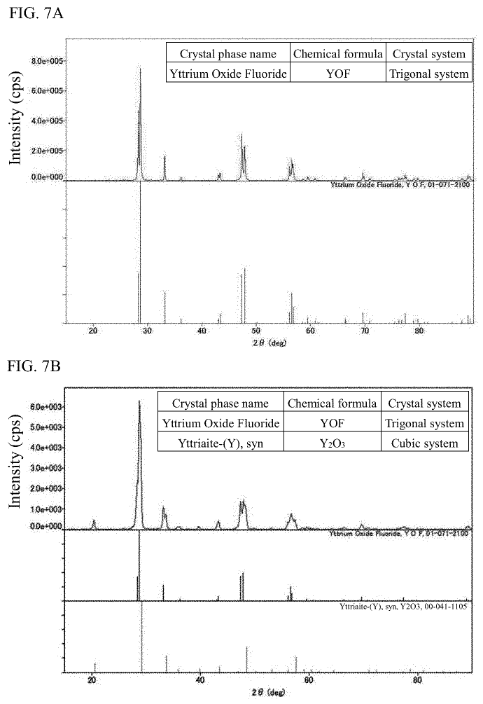

FIGS. 6A and 6B show each cross-sectional photograph of a thermal sprayed coating by SEM when the coating is formed from the YOF thermal spraying material in Comparative Example 1. FIG. 6A is a photograph of the thermal sprayed coating, which is observed at 3000 magnification. FIG. 6B is a photograph of the thermal sprayed coating, which is observed at 10000 magnification. The thickness of the thermal sprayed coating formed in Comparative Example 1 was about 20 μm. FIG. 7A shows the result of XRD measurement for the YOF thermal spraying material as the raw material powder. FIG. 7B shows the result of XRD measurement for the thermal sprayed coating formed in Comparative Example 1.

From the photographs of FIGS. 4A and 4B, it can be seen a dense thermal sprayed coating is formed in Example 1. When the porosity was calculated actually from the cross-sectional photograph of the thermal sprayed coating in FIG. 4A, it was 1.72%. On the other hand, from the photographs of FIGS. 6A and 6B, it can be seen a thermal sprayed coating having significantly reduced denseness is formed in Comparative Example 1. When the porosity was calculated actually from the cross-sectional photograph of the thermal sprayed coating in FIG. 6A, it was 8.75%.

When the result of XRD measurement for the raw material powder shown in FIG. 5A and the result of XRD measurement for the thermal sprayed coating shown in FIG. 5B were compared, it was found there was almost no change in the crystal structure and the chemical composition between the raw material powder and the formed thermal sprayed coating. On the other hand, when the result of XRD measurement for the raw material powder shown in FIG. 7A and the result of XRD measurement for the thermal sprayed coating shown in FIG. 7B were compared, it was observed there was change in the crystal structure and the chemical composition between the raw material powder and the formed thermal sprayed coating. Specifically, only YOF was observed in the case of the raw material powder, while a large amount of Y₂O₃ which seemed to be decomposed from YOF was observed in addition to YOF after the thermal sprayed coating was formed. As described above, according to the low pressure plasma spraying of Example 1, it was confirmed transformation of the raw material powder could be suppressed and a more dense thermal sprayed coating could be formed even when the same raw material powder was used.

### Example 2

An aluminum flat plate having a length of 50 mm, a width of 50 mm, and a thickness of 5 mm was prepared as a substrate. The low pressure plasma spraying was performed under the same conditions as in Example 1 by using the aluminum flat plate and α-Al₂O₃ sintered-pulverized powder having an average particle size of 2.3 μm (grain size range: 1 to 4 μm) as a thermal spraying material. As the nozzle of the thermal spraying gun, one having the structure shown in FIG. 2B was used.

### Comparative Example 2

A flat plate of SS400 steel, having a length of 50 mm, a width of 50 mm, and a thickness of 5 mm, was prepared as a substrate. The low pressure plasma spraying was performed under the same conditions as in Comparative Example 1 by using the flat plate of SS400 steel and α-Al₂O₃ sintered-pulverized powder having an average particle size of 2.3 μm (grain size range: 1 to 4 μm) as a thermal spraying material. As the nozzle of the thermal spraying gun, one having the structure shown in FIG. 2B was used.

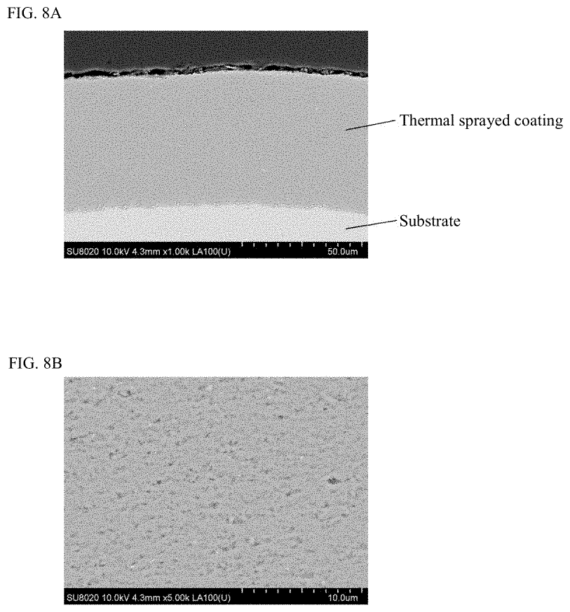

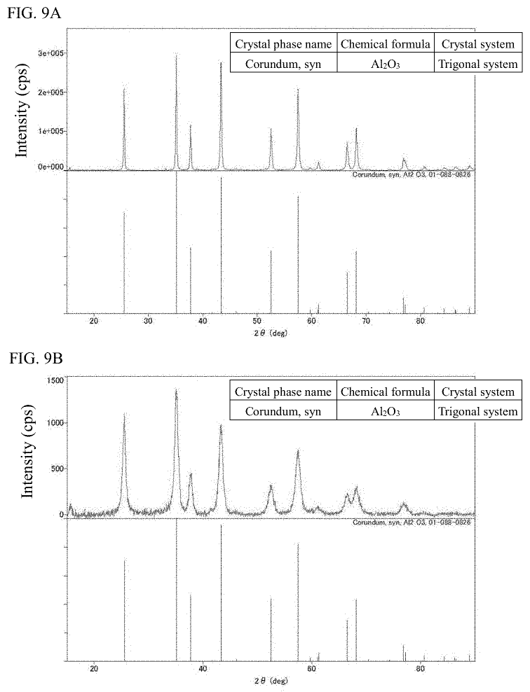

FIGS. 8A and 8B show each cross-sectional photograph of a thermal sprayed coating by SEM when the coating is formed from the α-Al₂O₃ thermal spraying material in Example 2. FIG. 8A is a photograph of the thermal sprayed coating, which is observed at 1000 magnification. FIG. 8B is a photograph of the thermal sprayed coating, which is observed at 5000 magnification. The thickness of the thermal sprayed coating formed in Example 2 was about 50 μm. FIG. 9A shows the result of XRD measurement for the α-Al₂O₃ thermal spraying material as the raw material powder. FIG. 9B shows the result of XRD measurement for the thermal sprayed coating formed in Example 2.

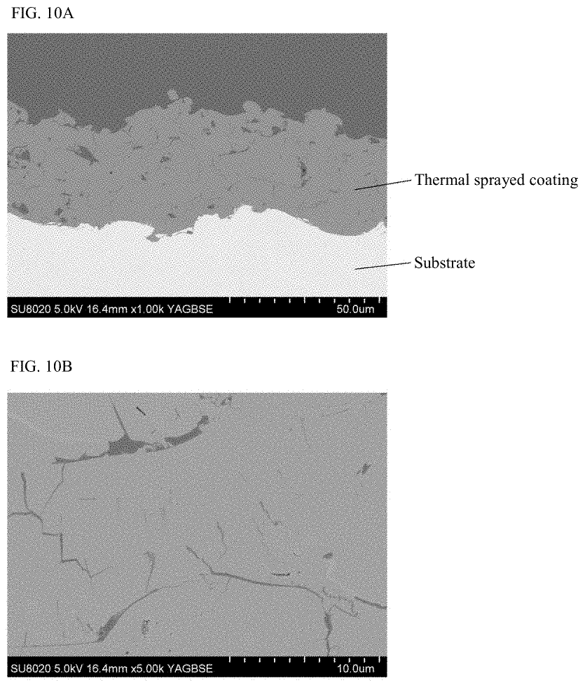

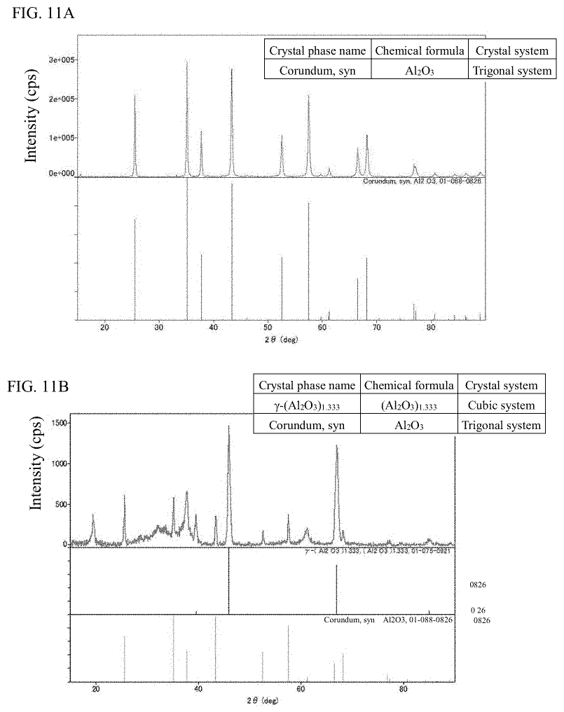

FIGS. 10A and 10B show each cross-sectional photograph of a thermal sprayed coating by SEM when the coating is formed from the α-Al₂O₃ thermal spraying material in Comparative Example 2. FIG. 10A is a photograph of the thermal sprayed coating, which is observed at 1000 magnification. FIG. 10B is a photograph of the thermal sprayed coating, which is observed at 5000 magnification. The thickness of the thermal sprayed coating formed in Comparative Example 2 was about 40 μm. FIG. 11A shows the result of XRD measurement for the α-Al₂O₃ thermal spraying material as the raw material powder. FIG. 11B shows the result of XRD measurement for the thermal sprayed coating formed in Comparative Example 2.

From the photographs of FIGS. 8A and 8B, it can be seen a dense thermal sprayed coating is formed in Example 2. When the porosity was calculated actually from the cross-sectional photograph of the thermal sprayed coating in FIG. 8A, it was 1.62%. On the other hand, from the photographs of FIG. 10, it can be seen a thermal sprayed coating having slightly reduced denseness is formed in Comparative Example 2. When the porosity was calculated actually from the cross-sectional photograph of the thermal sprayed coating in FIG. 10A, it was 4.86%.

When the result of XRD measurement for the raw material powder shown in FIG. 9A and the result of XRD measurement for the thermal sprayed coating shown in FIG. 9B were compared, it was found there was almost no change in the crystal structure and the chemical composition between the raw material powder and the formed thermal sprayed coating. On the other hand, when the result of XRD measurement for the raw material powder shown in FIG. 11A and the result of XRD measurement for the thermal sprayed coating shown in FIG. 11B were compared, it was observed there was change in the crystal structure between the raw material powder and the formed thermal sprayed coating. Specifically, only α-Al₂O₃ was observed in the case of the raw material powder, while a large amount of γ-Al₂O₃ was observed in addition to α-Al₂O₃ after the thermal sprayed coating was formed. As described above, according to the low pressure plasma spraying of Example 2, it was confirmed transformation of the raw material powder could be suppressed and a more dense thermal sprayed coating could be formed even when the same raw material powder was used.

The above embodiment is an example of the present invention and does not limit the present invention. The low pressure plasma spraying apparatus of the above embodiment is an example for carrying out the low pressure plasma spraying according to the present invention, and configuration of the low pressure plasma spraying apparatus may be appropriately changed according to a size and/or a shape of the object to be treated. The low pressure plasma spraying according to the present invention can be applied to various members and apparatuses such as, for example, plasma processing apparatuses in a semiconductor field, gas turbines in an aircraft field, heat sinks in an industrial machinery field, and batteries.

### DESCRIPTION OF REFERENCE CHARACTERS

1 Low pressure plasma spraying apparatus
2 Material feeding part
3 Thermal spraying gun
4 Plasma power source part
5 Six-axis robot
6 Pressure reducing vessel
7 Vacuum pump
8 Hopper
9 Conveying hose
10 Plasma jet
11 Feeding port
20 Substrate

1. A method of low pressure plasma spraying, the method comprising:
turning working gas into plasma to generate a plasma jet while setting a plasma power source output to 2 to 10 kW in a pressure reducing vessel; and
feeding raw material powder having an average particle size of 1 to 10 μm into the plasma jet to form a thermal sprayed coating.

2. The method according to claim 1, wherein powder having a particle size of 10 μm or more occupies 10 to 40% by volume of a total volume of the raw material powder.

3. The method according to claim 1, further comprising a pretreatment step of removing moisture in the raw material powder before feeding the raw material powder.

4. The method according to claim 3, wherein the pretreatment step is heat drying under vacuum.

5. The method according to claim 1, wherein a pressure within the pressure reducing vessel is 1 to 4 kPa.

6. The method according to claim 1, wherein the plasma jet is generated by direct-current arc.
